(19) United States
(12) Patent Application Publication
(10) Pub. No.: US 2009/0114428 A1
(43) Pub. Date: May 7, 2009

(54) PRINTED WIRING BOARD

(76) Inventor: Yukihiro UENO, Mihara-shi (JP)

Correspondence Address: BIRCH STEWART KOLASCH & BIRCH, PO BOX 747, FALLS CHURCH, VA, 22040-0747, US

(21) Appl. No.: 12/188,775

(22) Filed: Aug. 8, 2008

(30) Foreign Application Priority Data
Nov. 6, 2007 (JP) 2007-287983

(51) Int. Cl. H05K 1/00

(52) U.S. Cl. 174/254

(57) ABSTRACT

A printed wiring board which is sufficiently prevented from being damaged at the time of heating is provided. This printed wiring board comprises a flexible board having flexibility, a lamination portion which is formed on at least one surface of the flexible board and includes an insulation layer and a conductive layer laminated, and a barrier layer which is disposed between the flexible board and the lamination portion, or between the insulation layer and the conductive layer of the lamination portion and has water-vapor permeability lower than that of the insulation layer of the lamination portion.

This application is based on Japanese Patent Application No. 2007-287983 filed on Nov. 6, 2007, the contents of which are hereby incorporated by reference.

### BACKGROUND OF THE INVENTION

1. Field of the Invention

The present invention relates to a printed wiring board.

2. Description of Related Art

Conventionally, a printed wiring board comprising an insulation layer made of resin and a laminated conductive layer is known. Such a printed wiring board is disclosed, for example, in JP-A-1996-236941.

JP-A-1996-236941 discloses a multilayer printed wiring board (printed wiring board) having two glass epoxy double-sided copper clad laminate boards and epoxy resin prepreg disposed between the two glass epoxy double-sided copper clad laminate boards for adhesion of them. In this multilayer printed wiring board, the glass epoxy double-sided copper clad laminate comprises a base material including a glass clot and an epoxy resin, and two conductive patterns formed on both sides of the base material.

In the foregoing JP-A-1996-236941, a glass cloth having air permeability of 5 ml/cm²/s or less is used for the base material. This structure curbs moisture absorption of the epoxy resin prepreg which is disposed between the two glass epoxy double-sided copper clad laminate boards.

Also, conventionally, printed wiring boards such as a rigid flex (which is also called flex rigid or rigid flexible) board, a flexible board and the like which have partially flexibility are known.

FIG. 4 is a sectional view showing a structure of a conventional printed wring board which has flexibility. As shown in FIG. 4, a conventional printed wiring board 101 which has flexibility includes a flexible board 110 having flexibility, and rigid boards 120 formed on both sides of the flexible board 110. Besides, the printed wiring board 101 comprises a flexible region 101a where the rigid board 120 is not formed and a hard region 101b where the rigid board 120 is formed.

The flexible board 110 comprises a base film 111, conductive layers 112 which are made of copper or the like and formed on given regions of both sides of the base film 111, bond layers 113 which are disposed on the surfaces (the upper or lower surface) of the base film 111 and the conductive layers 112, and resin film layers 114 disposed on the surfaces of the bond layers 113. These base film 111, the bond layers 113 and the resin film layers 114 are formed of a resin such as polyimide, polyester, liquid crystal polymer, and bismaleimide-triazine.

The rigid board 120 comprises bond layers 121 disposed on both sides of the hard region 101b of the flexible board 110, insulation layers 122 disposed on the surface (the upper or lower surface) of the bond layers 121, and conductive layers 123 which are made of copper or the like and formed on given regions of the surfaces of the insulation layers 122. Besides, the bond layer 121 and the insulation layer 122 are formed of a glass-fiber reinforced epoxy resin.

Further, the printed wiring board 101 is provided with a plurality of viaholes 102 each of which is disposed on the upper or lower surface side of the flexible board 110 and connects the conductive layer 112 of the flexible board 110 with the conductive layer 123 of the rigid board 120. In addition, the printed wiring board 101 is also provided with a plurality of through-holes 103 each of which goes through the flexible board 110 (the base film 111) and connects the conductive layers 112, 123 formed on the upper surface side of the flexible board 110 with the conductive layers 112, 123 formed on the lower surface side of the flexible board 110. These viaholes 102 and through-holes 103 are filled with an electroconductive material (conductor) 104.

When mounting electronic components on the multiplayer printed wiring board disclosed in the JP-A-1996-236941 or on the conventional printed wiring board 101 having flexibility, or when removing electronic components from the boards, the printed wiring boards (the multilayer printed wiring board and the printed wiring board 101) are heated to a temperature of about 200° C. to about 260° C. Because a printed wiring board left in atmosphere absorbs moisture, if a printed wiring board containing moisture is heated, the moisture swells and causes layer separation and expansion of the printed wring board, and thereby the printed wiring board can be damaged.

Accordingly, when mounting electronic components on a printed wiring board or removing them from it, moisture removal (baking) is carried out on the printed wiring board in advance by heating it at a temperature of about 80° C. to about 130° C. for a time of dozens of minutes to a few hours. Thus, the printed wiring board is prevented form being damaged at the time of heating.

However, in recent years, a heating temperature is rising and a heating time is increasing because lead-free solder is used, and there is a problem that layer separation and expansion of a printed wiring board cannot be prevented at the time of heating by baking only, and it is hard to prevent the printed wiring board from being damaged by the layer separation and expansion.

As in the printed wiring board 101, if the base film 111 which is formed of a resin such as polyimide, polyester, liquid crystal polymer and bismaleimide-triazine is used, because the resins of polyimide, polyester, liquid crystal polymer and bismaleimide-triazine have relatively high moisture absorption, the printed wiring board 101 is especially easily damaged at the time of heating.

Because polyimide is a material that is relatively hard to be adhered, if the base film 111 is formed of polyimide, layer separation and expansion occur especially easily at the interface between the base film 111 and the bond layer 113.

If a plurality of conductive layers, bond layers, insulation layers and the like are laminated in a printed wiring board, once the base film and the like absorb moisture, it is hard to sufficiently remove the moisture even if baking is carried out. Accordingly, the printed wiring board is easily damaged at the time of heating.

### SUMMARY OF THE INVENTION

The present invention has been made to cope with the conventional problems, and it is an object of the present invention to provide a printed wiring board which is sufficiently prevented from being damaged at the time of heating.

To achieve the object, a printed wiring board according to a first aspect of the present invention comprises: a flexible board having flexibility; a lamination portion which is formed on at least one surface of the flexible board and includes an insulation layer and a conductive layer laminated; and a barrier layer which is disposed between the flexible board and the lamination portion, or between the insulation layer and the conductive layer of the lamination portion and has permeability to water vapor (water-vapor permeability) lower than that of the insulation layer of the lamination portion.

In the printed wiring board according to the first aspect, as described above, because the barrier layer is disposed between the flexible board and the lamination portion or between the insulation layer and the conductive layer of the lamination potion and has water-vapor permeability lower than that of the insulation layer of the lamination portion, it is possible to sufficiently prevent the water content from moving from the surface of the printed wiring board to the inside (the flexible board). In other words, it is possible to sufficiently prevent the flexible board and the insulation layer of the lamination portion from absorbing moisture. Accordingly, for example, at the time of heating to mount electronic components on the printed wiring board or to remove them form the printed wiring board, layer separation and expansion are sufficiently prevented from occurring to damage the printed wiring board.

In this case, even if the flexible board is formed of a resin such as polyimide, polyester, liquid crystal polymer and bismaleimide-triazine which have relatively high moisture absorption, because it is possible to sufficiently prevent the flexible board from absorbing moisture, the printed wiring board can be sufficiently prevented from being damaged at the time of heating.

In the printed wiring board according to the first aspect described above, the barrier layer is preferably formed on one surface side and the other surface side of the flexible board. According to this structure, because the flexible board and the insulation layer of the lamination portion and the like can be effectively prevented from absorbing moisture, it is possible to effectively prevent layer separation and expansion from occurring to damage the printed wiring board.

It is preferable that the printed wiring board according to the first aspect described above comprises a flexible region where the lamination portion is not formed and a hard region where the lamination portion is formed, and the barrier layer is formed on a surface of the flexible board in the flexible region. According to this structure, it is possible to easily prevent the flexible board from absorbing moisture in the flexible region. Besides, because the barrier layer is formed on a surface of the flexible board in the flexible region, when, in the hard region, forming the barrier layer between the flexible board and the lamination portion or between the insulation layer and the conductive layer of the lamination portion, the barrier layer can be formed on the entire surfaces (the entire regions) of the flexible region and the hard region. Accordingly, when forming the barrier layer, because a mask is not necessary, the barrier layer can be easily formed.

In the printed wiring board according to the first aspect described above, when the lamination portion includes one conductive layer, it is preferable that the barrier layer is disposed between the flexible board and the insulation layer of the lamination portion, and when the lamination portion includes a plurality of insulation layers and a plurality of conductive layers, it is preferable that the barrier layer is disposed between the second conductive layer (the second outermost conductive layer) of the plurality of conductive layers from the outside in the lamination portion and the outermost insulation layer of the plurality of insulation layers in the lamination portion. According to this structure, when the lamination portion includes one conductive layer, it is possible to sufficiently prevent the flexible board from absorbing moisture. And when the lamination portion includes a plurality of insulation layers and a plurality of conductive layers, it is possible to prevent the insulation layers inside the second outermost conductive layer and the flexible board from absorbing moisture. Besides, when the lamination portion includes a plurality of insulation layers and a plurality of conductive layers, if a barrier layer is disposed between the second outermost conductive layer of the plurality of conductive layers in the lamination portion and the outermost insulation layer of the plurality of insulation layers in the lamination portion, the numbers of insulation layers and conductive layers disposed outside the second outermost conductive layer can be each reduced to one. Thus, when carrying out baking, it becomes easy to remove moisture from the layers (the insulation layers and the like) outside the second outermost conductive layer. Consequently, it is possible to more sufficiently prevent the printed wiring board from being damaged at the time of heating.

In the printed wiring board according to the first aspect, the barrier layer is preferably formed of an oxide film. According to this structure, water-vapor permeability of the barrier layer can be made easily smaller than that of the insulation layer of the lamination portion.

In a printed wiring board whose barrier layer is formed of an oxide film, it is preferable that the barrier layer is formed of a silicon oxide film, an aluminum oxide film, or a magnesium oxide film. According to this structure, water-vapor permeability of the barrier layer can be made sufficiently smaller than that of the insulation layer of the lamination portion.

In the printed wiring board whose barrier layer is formed of an oxide film, it is preferable that the barrier layer is formed by vacuum evaporation, spattering, or chemical vapor deposition. With such a process, the barrier layer including an oxide film can be easily formed.

### BRIEF DESCRIPTION OF THE DRAWINGS

FIG. 1 is a sectional view showing a structure of a printed wiring board according to a first embodiment of the present invention.

FIG. 2 is a sectional view showing a structure of a flexible board of the printed wiring board shown in FIG. 1 according to the first embodiment of the present invention.

FIG. 3 is a sectional view showing a structure of a printed wiring board according to a second embodiment of the present invention.

FIG. 4 is a sectional view showing a structure of the conventional printed wiring board having flexibility.

### DETAILED DESCRIPTION OF PREFERRED EMBODIMENTS

Hereinafter, embodiments of the present invention are explained referring to the drawings.

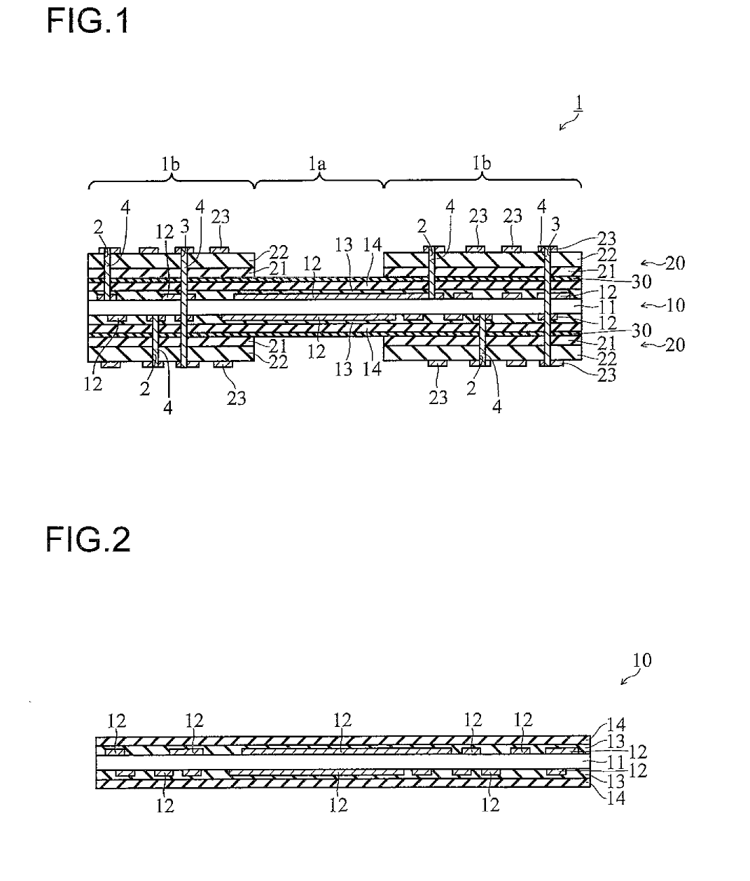

First Embodiment: First, referring to FIGS. 1 and 2, a structure of a printed wiring board according to a first embodiment of the present invention is explained.

As shown in FIG. 1, a printed wiring board 1 according to the first embodiment of the present invention has flexibility and comprises a flexible board 10 as the core of the printed wiring board 1, rigid boards 20 formed on both sides (the upper and lower surfaces) of the flexible board 10, and barrier layers 30 each disposed between the flexible board 10 and the rigid board 20. Besides, the printed wiring board 1 comprises a flexible region 1a which does not include the rigid board 20 and has flexibility and a hard region 1b where the rigid boards 20 are formed. The rigid board 20 is an example of a “lamination portion” of the present invention. Besides, the upper surface is an example of “one surface” of the present invention, and the lower surface is an example of “the other surface” of the present invention.

This flexible region 1a is so formed as to electrically connect one hard region 1b with the other hard region 1b, and to electrically connect the hard regions 1b with another wiring board and electronic apparatuses (not shown). Besides, the hard region 1b has a structure in which electronic components (not shown) are mounted and the electronic components are electrically connected with each other.

As shown in FIG. 2, the flexible board 10 comprises a base film 11, conductive layers 12 which are made of copper or the like and formed on given regions of both surfaces (the upper and lower surfaces) of the base film 11, bond layers 13 each of which is disposed on a surface (the upper or lower surface) of the base film 11 and each of the conductive layers 12, and resin film layers 14 each of which is disposed on a surface (the upper or lower surface) of each of the bond layers 13. These base film 11, bond layers 13 and resin film layers 14 are each formed of a resin such as polyimide, polyester, liquid crystal polymer and bismaleimide-triazine. According to this structure, the flexible board 10 has good flexing resistance, heat resistance, electric characteristics etc.

Here, in the first embodiment, the barrier layer 30 is formed on the upper and lower surface sides of the flexible board 10. Specifically, the barrier layer 30 is disposed on the upper surface of the resin film layer 14 disposed on the upper surface side of the flexible board 10, and is also disposed on the lower surface of the resin film layer 14 disposed on the lower surface side of the flexible board 10. Besides, the barrier layer 30 is formed on the surfaces of the flexible board 10 (the resin film layers 14) in both of the flexible region 1a and the hard region 1b.

Besides, the barrier layers 30 has water-vapor permeability lower than those of an bond layer 21 and an insulation layer 22 explained later of the rigid board 20, and is formed of an oxide film such as a silicon oxide film, an aluminum oxide film and a magnesium oxide film. Further, the barrier layer 30 is formed by vacuum evaporation, spattering or chemical vapor deposition.

The barrier layer 30 has a thickness of about 10 nm to about 200 nm. Because the barrier layer 30 is so formed as to have such a thickness of about 10 nm or more, the barrier performance of the barrier layer 30 to water vapor (water content) can be prevented from becoming low. Because the barrier layer 30 is made of an oxide film such as a silicon oxide film, an aluminum oxide film and a magnesium oxide film, it is vulnerable to damage and inferior in flexibility and stretchability to the base film 11, the bond layer 13, the resin film layer 14, a bond layer 21, and an insulation layer 22. However, because the barrier layer 30 is so formed as to have a thickness of about 200 nm or less, even when the printed wiring board 1 is bent, it is possible to prevent cracks and the like from appearing in the barrier layer 30, and even when layer separation stress acts on the barrier layer 30, the barrier layer 30 can be prevented from being damaged.

The rigid board 20 comprises an bond layer 21 which is formed on both surfaces (the upper and lower surfaces) of the hard region 1b of the flexible board 10 via the barrier layer 30, an insulation layer 22 disposed on a surface (the upper or lower surface) of the bond layer 21, and a conductive layer 23 which is made of copper or the like and disposed on a given region of a surface (the upper or lower surface) of the insulation layer 22. The bond layer 21 and the insulation layer 22 are each formed of a glass-fiber reinforced epoxy resin or the like. Electronic components (not shown) and the like are mounted on the conductive layer 23 with the entire printed wiring board 1 heated.

A plurality of viaholes 2 are formed on the printed wiring board 1, each of them is disposed on the upper or lower surface side of the flexible board 10 and connects the conductive layer 12 of the flexible board 10 with the conductive layer 23 of the rigid board 20. In addition, a plurality of through-holes 3 are also formed in the printed wiring board 1, and each of them goes through the flexible board 10 (the base film 11) and connects the conductive layers 12, 23 formed on the upper surface side of the flexible board 10 with the conductive layers 12, 23 formed on the lower surface side of the flexible board 10. The viaholes 2 and through-holes 3 are filled with a conductor 4 formed of copper or the like. These viaholes 2, through-holes 3 and conductors 4 have a function to electrically connect electronic components (not shown) mounted on the conductive layer 23 with each other.

Next, referring to FIGS. 1 and 2, a fabrication method of the printed wiring board 1 according to the first embodiment of the present invention is explained.

First, the flexible board 10 shown in FIG. 2 and comprising the base film 11, the conductive layers 12 each having a given pattern, the bond layers 13 and the resin film layers 14 is prepared. And baking is sufficiently applied to the flexible board 10 holding it at a temperature of about 90° C. or higher for about 30 minutes or longer. At this time, the baking is preferably carried out at a temperature of 100° C., that is, the boiling point of water or higher. In the first embodiment, baking is carried out at a temperature of 130° C. and for about 1 hour.

Then plasma treatment is applied to both the entire surfaces (the upper and lower surfaces) of the flexible board 10 in a 100%-oxygen atmosphere and in a range of about 10 W/cm² to about 50 W/cm².

And as shown in FIG. 1, both the entire surfaces (the upper and lower surfaces) of the flexible board 10 are processed by vacuum evaporation, spattering or chemical vapor deposition to form thereon the barrier layers 30 each comprising an oxide film such as a silicon oxide film, an aluminum oxide film and a magnesium oxide film. At this time, the barrier layer 30 is so formed as to have a thickness of about 10 nm to about 200 nm.

If the barrier layer 30 formed of a silicon oxide film is made by spattering, silicon oxide is used as a target and argon gas is used as a discharge gas.

Before the barrier layer 30 is formed, plasma treatment is applied to both the entire surfaces of the flexible board 10, thereby adhesion between the barrier layer 30 and the flexible board 10 (the resin film layer 14) can be enhanced.

Then, on regions to be the hard regions 1b on both surfaces (the upper and lower surfaces) of the barrier layer 30, the following layers are laminated successively from near the flexible board 10 in the following order of: the bond layer 21 (directly on the barrier layer 30), the insulation layer 22 and the conductive layer 23. Then, they are bonded by thermo-compression bonding. In this case, it is preferable that plasma treatment is applied to the entire surfaces of the barrier layer 30 before the bond layer 21, the insulation layer 22 and the conductive layer 23 are laminated on the surfaces of the barrier layer 30 and bonded by thermo-compression bonding. According to these processes, because the barrier layer 30 and the bond layer 21 can be bonded to each other with both surfaces (the upper and lower surfaces) of the barrier layer 30 activated, it is possible to further enhance adhesion between the barrier layer 30 and the bond layer 21.

Then, a pattern is formed on the conductive layer 23 by photolithography or etching. And after the viaholes 2 and through-holes 3 are formed by laser machining or the like, the viaholes 2 and through-holes 3 are filled with the conductors 4 by plating or the like.

As explained above, the printed wiring board 1 according to the first embodiment is fabricated.

The other fabricating methods of the printed wiring board 1 are the same as those known conventionally.

In the first embodiment, as described above, because the barrier layer 30 disposed between the flexible board 10 and the rigid board 20 has water-vapor permeability lower than those of the bond layer 21 and the insulation layer 22 of the rigid board 20, it is possible to sufficiently prevent the water content from moving from the rigid board 20 to the flexible board 10, and it is also possible to sufficiently prevent the flexible board 10 from absorbing moisture. In this way, for example, at the time of heating to mount electronic components (not shown) on the printed wiring board 1 or to remove them, it is possible to sufficiently prevent layer separation and expansion from occurring in the flexible board 10 to damage the printed wiring board 1.

As in the first embodiment, even when the flexible board 10 is formed of a resin such as polyimide, polyester, liquid crystal polymer and bismaleimide-triazine which have relatively high moisture absorption, it is possible to sufficiently prevent the flexible board 10 from absorbing moisture, thereby the printed wiring board 1 can be sufficiently prevented from being damaged at the time of heating.

Besides, even if the flexible board 10 is made of polyimide which is relatively hard to be bonded, the flexible board 10 can be sufficiently prevented from absorbing moisture, thereby layer separation and expansion can be sufficiently prevented from occurring in the interface between the base film 1 and the bond layer 13 of the flexible board 10.

Further, in the first embodiment, because the barrier layer 30 is disposed on the upper and lower surface sides of the flexible board 10, the flexible board 10 can be effectively prevented from absorbing moisture, thereby layer separation and expansion can be effectively prevented from occurring to damage the printed wiring board 1 at the time of heating.

In the first embodiment, because the barrier layer 30 is formed on the surfaces of the flexible board 10 in the flexible region 1a, the flexible board 10 can be easily prevented from absorbing moisture in the flexible region 1a. Also, because the barrier layer 30 is formed on the surfaces of the flexible board 10 in the flexible region 1a, when forming the barrier layer 30 on the surfaces of the flexible board 10 in the hard region 1b, the barrier layer 30 can be formed on the entire surfaces (the entire regions) of the flexible region 1a and the hard region 1b. Accordingly, a mask and the like are not necessary and the barrier layer 30 can be easily formed.

In the first embodiment, because the barrier layer 30 is made of an oxide film such as a silicon oxide film, an aluminum oxide film and a magnesium oxide film, the water-vapor permeability of the barrier layer 30 can be made easily lower than those of the bond layer 21 and the insulation layer 22 of the rigid board 20.

Moreover, in the first embodiment, because the barrier layer 30 is formed by vacuum evaporation, spattering or chemical vapor deposition, the barrier layer 30 can be easily formed of an oxide film such as a silicon oxide film, an aluminum oxide film and a magnesium oxide film.

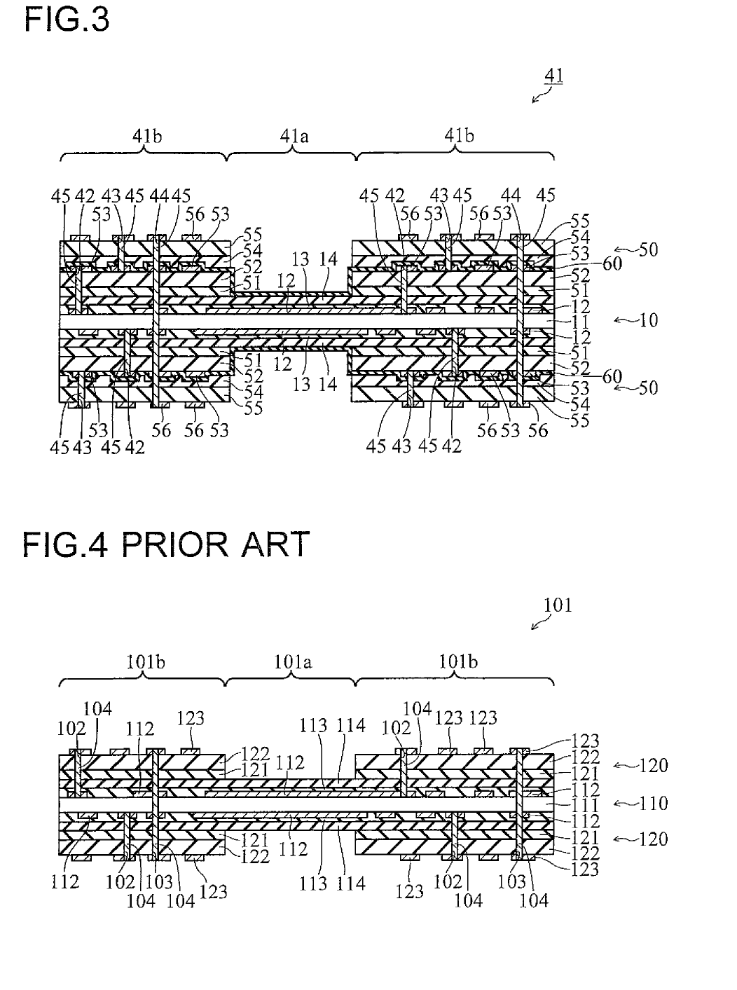

Second Embodiment: Referring to FIG. 3, a second embodiment is explained. The second embodiment is different from the first embodiment in that a part of a barrier layer is disposed inside a rigid board.

As shown in FIG. 3, a printed wiring board 41 according to a second embodiment of the present invention comprises the flexible board 10 having the same structure as that in the first embodiment, rigid boards 50 formed on both sides (the upper and lower surfaces) of the flexible board 10, and a barrier layer 60 a part of which is disposed inside the rigid board 50. Besides, the printed wiring board 41 comprises a flexible region 41a which does not include the rigid board 50 and has flexibility and a hard region 41b where the rigid boards 50 are formed. The rigid board 50 is an example of a “lamination portion” of the present invention.

In the second embodiment, the rigid board 50 is different from that in the first embodiment that it includes two bond layers 51 and 54, two insulation layers 52 and 55, and two conductive layers 53 and 56. Specifically, the rigid board 50 comprises a bond layer 51, an insulation layer 52, a conductive layer 53, a bond layer 54, an insulation layer 55 and a conductive layer 56 which are formed on both sides (the upper and lower surfaces) of the hard region 41b of the flexible board 10. The conductive layer 53 is an example of “the second outermost conductive layer,” and the insulation layer 55 is an example of “the outermost insulation layer.”

As in the first embodiment, the bond layer 51, the insulation layer 52, the bond layer 54 and the insulation layer 55 are formed of a glass-fiber reinforced epoxy resin or the like. Electronic components (not shown) are mounted on the conductive layer 56 with the entire printed wiring board 41 heated.

Here, in the second embodiment, the barrier layer 60 is formed on the flexible board 10 (the resin film layer 14) in the flexible region 41a. On the other hand, in the hard region 41b, the barrier layer 60 is formed between the insulation layer 52 and the bond layer 54 of the rigid board 50 and between the conductive layer 53 and the bond layer 54 of the rigid board 50. In other words, in the hard region 41b, the barrier layer 60 is disposed between the second outermost conductive layer 53 of the two conductive layers 53, 56 of the rigid board 50 and the outermost insulation layer 55 of the two insulation layers 52, 55 of the rigid board 50.

Also, in the second embodiment, the barrier layer 60, as in the first embodiment, has water-vapor permeability lower than those of the bond layer 51, the insulation layer 52, the bond layer 54 and the insulation layer 55.

Besides, the printed wiring board 41 is provided with a plurality of viaholes 42 and 43, and a plurality of through-holes 44. The viaholes 42 are disposed on the upper and lower surface sides of the flexible board 10, and connects the conductive layer 12 of the flexible board 10 with the conductive layer 53 of the rigid board 50. The viaholes 43 are disposed on the upper and lower surface sides of the flexible board 10, and connects the conductive layer 53 with the conductive layer 56 of the rigid board 50. The through-hole 44 goes through the flexible board 10 (the base film 11) and connects the conductive layers 12, 53 and 56 formed on the upper surface side of the flexible board 10 with the conductive layers 12, 53 and 56 formed on the lower surface side of the flexible board 10. These viaholes 42 and 43, and the through-holes 44 are each filled with a conductor 45 formed of copper or the like.

The other structures of the printed wiring board 41 are the same as those in the first embodiment.

Next, referring to FIG. 3, a fabrication method of the printed wiring board 41 according to the second embodiment of the present invention is explained.

First, the flexible board 10 is prepared. And, on regions to be the hard regions 41b on the surfaces (the upper and lower surfaces) of the flexible board 10 (the resin film layer 14), the following layers are laminated successively from near the flexible board 10 in the following order of: the bond layer 51, the insulation layer 52 and the conductive layer 53. Then, they are bonded by thermo-compression bonding.

Then, a pattern is formed on the conductive layer 53 by photolithography or etching. And after the viaholes 42 are formed by laser machining or the like, the viaholes 42 are filled with the conductors 45 by plating or the like.

And baking is sufficiently applied to the printed wiring board 41 (the flexible board 10, the bond layer 51 and the insulation layer 52 of the rigid board 50) holding it at a temperature of about 130° C. for about 1 hour.

Then, plasma treatment is applied to both the entire surfaces (the upper and lower surfaces) of the insulation layer 52 and the conductive layer 53 and to both the entire surfaces of the flexible region 41a of the flexible board 10 in a 100%-oxygen atmosphere and in a range of about 10 W/cm² to about 50 W/cm².

Thereafter, both of the entire surfaces of the insulation layer 52 and the conductive layer 53, and both of the entire surfaces of the flexible region 41a of the flexible board 10 are processed by vacuum evaporation, spattering or chemical vapor deposition to form thereon the barrier layers 60 each comprising an oxide film such as a silicon oxide film, an aluminum oxide film and a magnesium oxide film.

Then, on the hard regions 41b on both surfaces (the upper and lower surfaces) of the barrier layer 60, the following layers are laminated successively from near the barrier layer 60 in the following order of: the bond layer 54, the insulation layer 55 and the conductive layer 56. Then, they are bonded by thermo-compression bonding. In this case, it is preferable that plasma treatment is applied to the entire surfaces of the barrier layer 60 before the bond layer 54, the insulation layer 55 and the conductive layer 56 are laminated on the surfaces of the barrier layer 60 and bonded by thermo-compression bonding.

Thereafter, a pattern is formed on the conductive layer 56 by photolithography or etching. And after the viaholes 43 and through-holes 44 are formed by laser machining or the like, the viaholes 43 and through-holes 44 are filled with the conductors 45 by plating or the like.

As explained above, the printed wiring board 41 according to the second embodiment is fabricated.

The other fabricating methods of the printed wiring board 41 are the same as those in the first embodiment.

In the second embodiment, as described above, because the barrier layer 60 disposed between the conductive layer 53 and the bond layer 54 (the insulation layer 55) of the rigid board 50 has water-vapor permeability lower than those of the bond layers 51, 53, the insulation layers 52, 55, it is possible to sufficiently prevent the water content from moving from the outside (the insulation layer 55 and the bond layer 54) of the rigid board 50 to the inside (the insulation layer 52, the bond layer 51 and the flexible board 10) of the rigid board 50. In other words, it is possible to sufficiently prevent the bond layer 51 and the insulation layer 52 of the rigid board 50 and the flexible board 10 from absorbing moisture. In this way, at the time of heating to mount electronic components (not shown) on the printed wiring board 41 or to remove them, it is possible to sufficiently prevent layer separation and expansion from occurring in the flexible board 10, the bond layer 51 and the insulation layer 52 of the rigid board 50 to damage the printed wiring board 41.

Besides, in the second embodiment, because the barrier layer 60 is formed on the surfaces (the upper and lower surfaces) of the flexible board 10 (the resin film layer 14) in the flexible region 41a, the flexible board 10 can be easily prevented from absorbing moisture in the flexible region 41a. Also, when the barrier layer 60 is formed on the surfaces of the insulation layer 52 and the conductive layer 53 in the hard region 41b, the barrier layer 60 can be formed on the entire surfaces of the flexible region 41a and the hard region 41b. Accordingly, a mask and the like are not necessary, and the barrier layer 60 can be easily formed.

In addition, in the second embodiment, the barrier layer 60 is disposed between the second outermost conductive layer 53 of the two conductive layers 53 and 56 of the rigid board 50 and the outermost insulation layer 55 of the two insulation layers 52 and 55 of the rigid board 50. According to this structure it is possible to sufficiently prevent the insulation layer 52, the bond layer 51 and the flexible board 10 of the rigid board 50 which are formed inside the barrier layer 60 from absorbing moisture. Further, because only one of each of the bond layer, the insulation layer and the conductive layer which are disposed outside the barrier layer 60 is enough, when carrying out baking before heating, it is easy to remove moisture from the layers (the bond layer 54 and the insulation layer 55) outside the barrier layer 60. Consequently, it is possible to more sufficiently prevent the printed wiring board 41 from being damaged at the time of heating.

The other effects in the second embodiment are the same as those in the first embodiment.

The embodiments disclosed above should be considered as only examples and are not limiting in every respect. The scope of the present invention should not be represented by the explanation of the embodiments described above but by the claims and includes any modifications made within the scope and meaning equivalent to the scope of the claims.

In the embodiments explained above, the present invention is applied to the printed wiring board in which the flexible region and the hard regions are disposed. However, the present invention is not limited to such printed wiring board, and may be applied, for example, to a printed wiring board including a multiplayer flexible board in which a hard region is not formed.

In the embodiments explained above, the barrier layer is formed on the upper and lower surface sides of the flexible board. However, the present invention is not limited to this structure, and the barrier layer may be formed, for example, on only the upper surface side of the flexible board. Also in this case, if a metal layer or the like is formed on substantially the entire plane of the lower surface side of the flexible board, the flexile board can be sufficiently prevented from absorbing moisture.

In the embodiments explained above, the barrier layer comprising one layer is formed on the upper and lower surface sides of the flexible board. However, the present invention is not limited to this structure, and a barrier layer comprising two layers may be formed on only the upper surface side of the flexible board. In this case, a layer disposed between the two barrier layers can be sufficiently prevented from absorbing moisture.

Besides, in the embodiments explained above, the barrier layer is formed by using vacuum evaporation, spattering, or chemical vapor deposition. However, the present invention is not limited to these processes, and the barrier layer may be formed by another one rather than these processes.

In the second embodiment explained above, in the structure that the rigid board comprises the plurality of conductive layers and the plurality of insulation layers, the barrier layer is disposed between the second outermost conductive layer of the plurality of conductive layers and the outermost insulation layer of the plurality of insulation layers. However, the present invention is not limited to this structure, and even when the rigid board comprises the pluralty of conductive layers and the plurality of insulation layers, the barrier layer may be disposed between the flexible board and the rigid board as in the first embodiment.

In the embodiments explained above, the rigid board (the lamination portion) comprises one or two conductive layers. However, the present invention is not limited to this structure, and the conductive layer of the rigid board may comprise more than two layers. Specifically, the preset invention can be applied to a printed wiring board which has eight or more conductive layers.

When mounting electronic components on the printed wiring board according to the present invention or removing them, baking may be or may not be applied to the printed wiring board. However, it is preferable that baking is carried out.

What is claimed is:

1. A printed wiring board, comprising:
a flexible board having flexibility;
a lamination portion which is formed on at least one surface of the flexible board, and includes an insulation layer and a conductive layer laminated; and
a barrier layer which is disposed between the flexible board and the lamination portion, or between the insulation layer and the conductive layer of the lamination portion and has water-vapor permeability lower than that of the insulation layer of the lamination portion.

2. The printed wiring board according to claim 1, wherein the barrier layer is formed on one surface side and on the other surface side of the flexible board.

3. The printed wiring board according to claim 1, comprising a flexible region where the lamination portion is not formed and a hard region where the lamination portion is formed, and the barrier layer is formed on a surface of the flexible board in the flexible region.

4. The printed wiring board according to claim 1, wherein
when the lamination portion includes one conductive layer, the barrier layer is disposed between the flexible board and the insulation layer of the lamination portion, and
when the lamination portion includes a plurality of insulation layers and a plurality of conductive layers, the barrier layer is disposed between the second conductive layer of the plurality of conductive layers from the outside in the lamination portion and the outermost insulation layer of the plurality of insulation layers in the lamination portion.

5. The printed wiring board according to claim 1, wherein the barrier layer is formed of an oxide film.

6. The printed wiring board according to claim 5, wherein the barrier layer is formed of one of a silicon oxide film, an aluminum oxide film and a magnesium oxide film.

7. The printed wiring board according to claim 5, wherein the barrier layer is formed by one of vacuum evaporation, spattering and chemical vapor deposition.

8. The printed wiring board according to claim 5, wherein the barrier layer has a thickness of 10 nm or more.

9. The printed wiring board according to claim 5, wherein the barrier layer has a thickness of 200 nm or less.

10. The printed wiring board according to claim 1, wherein the flexible board is formed of a resin of polyimide, polyester, liquid crystal polymer and bismaleimide-triazine.

11. The printed wiring board according to claim 1, wherein the insulation layer of the lamination portion includes a glass-fiber reinforced epoxy resin.

12. The printed wiring board according to claim 1, comprising a flexible region where the lamination portion is not formed and a hard region where the lamination portion is formed, and the barrier layer is formed on the entire regions of the flexible region and the hard region.

13. The printed wiring board according to claim 1, wherein
plasma treatment is applied to at least one surface of the flexible board, and
the barrier layer is disposed on the one surface treated with plasma of the flexible board.
